(19) United States
(12) Patent Application Publication
(10) Pub. No.: US 2021/0066652 A1
(43) Pub. Date: Mar. 4, 2021

(54) DISPLAY APPARATUS

(71) Applicant: SAMSUNG DISPLAY CO., LTD., Yongin-si (KR)

(72) Inventors: Minsu LEE, Yongin-si (KR); Richard JAMES, Yongin-si (KR); Deokhoi KIM, Yongin-si (KR)

(21) Appl. No.: 16/836,995

(22) Filed: Apr. 1, 2020

(30) Foreign Application Priority Data
Sep. 4, 2019 (KR) 10-2019-0109649

(51) Int. Cl. H01L 51/52

(52) U.S. Cl. CPC H01L 51/5253; H01L 2251/558; H01L 2251/303

(57) ABSTRACT

A display apparatus including: a substrate including a display area and a non-display area; a display layer including a first display element and a second display element arranged in the display area; and a thin-film encapsulation layer arranged to cover the display layer and including at least one organic encapsulation layer and at least one inorganic encapsulation layer, wherein the at least one organic encapsulation layer and the at least one inorganic encapsulation layer are alternately stacked, wherein a refractive index of the at least one inorganic encapsulation layer is greater than a refractive index of the at least one organic encapsulation layer, and a thickness of a first portion of the at least one inorganic encapsulation layer corresponding to the first display element is different from a thickness of a second portion of the at least one inorganic encapsulation layer corresponding to the second display element.

### CROSS-REFERENCE TO RELATED APPLICATION

This application claims priority under 35 U.S.C. § 119 to Korean Patent Application No. 10-2019-0109649, filed on Sep. 4, 2019, in the Korean Intellectual Property Office, the disclosure of which is incorporated by reference herein in its entirety.

### TECHNICAL FIELD

One or more exemplary embodiments of the present invention relate to a display apparatus, and more particularly, to a display apparatus including a thin-film encapsulation layer.

### DISCUSSION OF THE RELATED ART

As the information-oriented society develops, the desire for display apparatuses displaying images, in various forms and designs, is increasing. The field of display apparatuses has rapidly changed from relatively large cathode ray tubes (CRT) to flat-panel display devices (FPD), which are relatively thin and light, and may include a relatively large display area. The FPDs include liquid-crystal display devices (LCD), plasma display panels (PDP), organic light-emitting display devices (OLED), electrophoretic display devices (EPD), or the like.

The above-stated display apparatuses may typically include a thin-film encapsulation layer on a display layer displaying an image, and the thin-film encapsulation layer may include at least one inorganic encapsulation layer and at least one organic encapsulation layer.

### SUMMARY

According to an exemplary embodiment of the present invention, a display apparatus including: a substrate including a display area and a non-display area; a display layer including a first display element and a second display element arranged in the display area; and a thin-film encapsulation layer arranged to cover the display layer and including at least one organic encapsulation layer and at least one inorganic encapsulation layer, wherein the at least one organic encapsulation layer and the at least one inorganic encapsulation layer are alternately stacked, wherein a refractive index of the at least one inorganic encapsulation layer is greater than a refractive index of the at least one organic encapsulation layer, and a thickness of a first portion of the at least one inorganic encapsulation layer corresponding to the first display element is different from a thickness of a second portion of the at least one inorganic encapsulation layer corresponding to the second display element.

In an exemplary embodiment of the present invention, the at least one inorganic encapsulation layer of the thin-film encapsulation layer includes a first inorganic encapsulation layer, and a second inorganic encapsulation layer, and the at least one organic encapsulation layer of the thin-film encapsulation layer includes an organic encapsulation layer, wherein the first inorganic encapsulation layer, the organic encapsulation layer and the second inorganic encapsulation layer are stacked, a first thickness of the second inorganic encapsulation layer corresponding to the first display element is different from a second thickness of the second inorganic encapsulation layer corresponding to the second display element.

In an exemplary embodiment of the present invention, the first display element emits red light and the second display element emits green light, and the first thickness is greater than the second thickness.

In an exemplary embodiment of the present invention, the display layer further includes a third display element, and a third thickness of the second inorganic encapsulation layer corresponding to the third display element is different from the first thickness and the second thickness.

In an exemplary embodiment of the present invention, the first display element emits red light, the second display element emits blue light, and the third display element emits green light, the first thickness is greater than the second thickness, and the second thickness is greater than the third thickness.

In an exemplary embodiment of the present invention, the display apparatus further includes an input sensing unit arranged on the thin-film encapsulation layer and includes a sensing electrode and at least one inorganic film, wherein the at least one inorganic encapsulation layer is connected to the at least one inorganic film, and a first total thickness of the first portion of the at least one inorganic encapsulation layer and the at least one inorganic film, each of which correspond to the first display element, is different from a second total thickness of the second portion of the at least one inorganic encapsulation layer and the at least one inorganic film, each of which correspond to the second display element.

In an exemplary embodiment of the present invention, the at least one inorganic encapsulation layer of the thin-film encapsulation layer includes a first inorganic encapsulation layer, and a second inorganic encapsulation layer, and the at least one organic encapsulation layer of the thin-film encapsulation layer includes an organic encapsulation layer, wherein the first inorganic encapsulation layer, the organic encapsulation layer and the second inorganic encapsulation layer are stacked, the at least one inorganic film includes a first inorganic film, and the second inorganic encapsulation layer is connected to the first inorganic film.

In an exemplary embodiment of the present invention, the sensing electrode is disposed between the first display element and the second display element.

In an exemplary embodiment of the present invention, the input sensing unit further includes an organic insulating layer disposed on the sensing electrode.

In an exemplary embodiment of the present invention, a thickness of the organic encapsulation layer is about 3 μm to about 15 μm, a refractive index of the first inorganic encapsulation layer is about 1.55 to about 1.85, and at least one of a thickness of the first inorganic encapsulation layer, the first thickness of the second inorganic encapsulation layer, or the second thickness of the second inorganic encapsulation layer is less than the thickness of the organic encapsulation layer.

In an exemplary embodiment of the present invention, the first thickness of the second inorganic encapsulation layer is about 0.7 μm, and the second thickness of the second inorganic encapsulation layer is about 0.8 μm.

In an exemplary embodiment of the present invention, the first inorganic encapsulation layer includes at least one of silicon oxide, silicon nitride, or silicon oxynitride.

In an exemplary embodiment of the present invention, the refractive index of he at least one organic encapsulation layer is about 1.45 to about 1.55.

In an exemplary embodiment of the present invention, the display apparatus further includes a planarization film disposed on the thin-film encapsulation layer.

According to an exemplary embodiment of the present invention, a display apparatus includes: a substrate including a display area and a non-display area; a display layer including a first display element and a second display element arranged in the display area; and a thin-film encapsulation layer arranged to cover the display layer and including a first inorganic encapsulation layer, an organic encapsulation layer, and a second inorganic encapsulation layer, wherein a refractive index of the organic encapsulation layer is less than refractive indices of the first inorganic encapsulation layer and the second inorganic encapsulation layer, a thickness of the organic encapsulation layer is about 3 μm to about 15 μm, the refractive index of the first inorganic encapsulation layer is about 1.55 to about 1.85, and a first thickness of a first portion of the second inorganic encapsulation layer corresponding to the first display element is different from a second thickness of a second portion of the second inorganic encapsulation layer corresponding to the second display element.

In an exemplary embodiment of the present invention, the display layer further includes a third display element, and a third thickness of a third portion of the second inorganic encapsulation layer corresponding to the third display element is different from the first thickness and the second thickness.

In an exemplary embodiment of the present invention, the display apparatus further includes an input sensing unit including an inorganic film and a sensing electrode disposed on the thin-film encapsulation layer, wherein a first total thickness of the first portion of the second inorganic encapsulation layer and the inorganic film, each of which correspond to the first display element, is different from a second total thickness of the second portion of the second inorganic encapsulation layer and the inorganic film, each of which correspond to the second display element.

In an exemplary embodiment of the present invention, the display apparatus further includes a planarization film disposed on the thin-film encapsulation layer.

In an exemplary embodiment of the present invention, at least one of a thickness of the first inorganic encapsulation layer, the first thickness of the first portion of the second inorganic encapsulation layer, or the second thickness of the second portion of the second inorganic encapsulation layer is less than the thickness of the organic encapsulation layer.

According to an exemplary embodiment of the present invention, a display apparatus includes: a substrate including a display area; a display layer including display elements arranged on the display area; and a thin-film encapsulation layer disposed on the display layer and including a first inorganic encapsulation layer, an organic encapsulation layer, and a second inorganic encapsulation layer, wherein a refractive index of the organic encapsulation layer is less than refractive indices of the first inorganic encapsulation layer and the second inorganic encapsulation layer, a thickness of the organic encapsulation layer is about 3 μm to about 15 μm, the refractive index of the first inorganic encapsulation layer is about 1.55 to about 1.85, and a thickness of the first inorganic encapsulation layer and a thickness of the second inorganic encapsulation layer are less than the thickness of the organic encapsulation layer.

### BRIEF DESCRIPTION OF THE DRAWINGS

The above and other features of the present invention will become more apparent by describing in detail exemplary embodiments thereof, with reference to the accompanying drawings, in which:

FIG. 1 is a schematic plan view of a display apparatus according, to an exemplary embodiment of the present invention;

FIG. 2 is a circuit diagram of a pixel included in a display apparatus according to an exemplary embodiment of the present invention;

FIG. 3 is a schematic cross-sectional view of a display apparatus according to an exemplary embodiment of the present invention;

FIG. 4 is a cross-sectional view illustrating a stacked structure of an input sensing unit according to an exemplary embodiment of the present invention;

FIG. 5 is a schematic cross-sectional view of a portion of a display apparatus according to an exemplary embodiment of the present invention;

FIG. 6 illustrates a simulation result of a comparative example for comparing with an exemplary embodiment of the present invention;

FIG. 7 is a schematic cross-sectional view of a display layer and a thin-film encapsulation layer of a display apparatus according to an exemplary embodiment of the present invention;

FIG. 8 is a schematic cross-sectional view of a portion of a display apparatus according to an exemplary embodiment of the present invention;

FIG. 9 is a schematic cross-sectional view of a display layer and a thin-film encapsulation layer of a display apparatus according to an exemplary embodiment of the present invention;

FIG. 10A is a schematic cross-sectional view of a portion of a display apparatus according to an exemplary embodiment of the present invention;

FIG. 10B is a schematic cross-sectional view of a display layer and a thin-film encapsulation layer of a display apparatus according to an exemplary embodiment of the present invention;

FIG. 11A illustrates a simulation result showing a relationship between reflectance of external light and a refractive index of a first inorganic encapsulation layer and a thickness of an organic encapsulation layer, according to an exemplary embodiment of the present invention; and

FIG. 11B illustrates a simulation result showing reflectance of external light according to a thickness of an organic encapsulation layer, according to an exemplary embodiment of the present invention.

### DETAILED DESCRIPTION OF THE EMBODIMENTS

Exemplary embodiments of the present invention will now be described more fully with reference to the accompanying drawings. It is to be understood that the present invention may be embodied in different forms and thus should not be construed as being limited to the exemplary embodiments set forth herein. It is to be understood that like reference numerals may refer to like elements throughout the specification, and thus redundant descriptions may be omitted. As used herein, the term “and/or” includes any and all combinations of one or more of the associated listed items.

While such terms as “first,” “second,” etc., may be used to describe various elements, such elements must not be limited to the above terms. These terms are only used to distinguish one element from another. Thus, a first element discussed below could be termed a second element without departing from the spirit and scope of the present invention.

It is to be understood that when a layer, region, or component is referred to as being “on” another layer, region, or component, the layer, region or component can be directly on the other layer, region, or component or intervening layers, regions or components may be present therebetween.

Sizes of components in the drawings may be exaggerated for clarity. In other words, since sizes and thicknesses of components in the drawings may be exaggerated for clarity, the following exemplary embodiments of the present invention are not limited thereto.

When an exemplary embodiment present invention may be implemented differently, a specific process order may be performed differently from a described order. For example, two consecutively described processes may be performed at substantially the same time or performed in an order opposite to the described order.

It will be understood that when a layer, region, or component is referred to as being connected to another layer, region, or component, the layer, region, or component can be directly or indirectly connected to the other layer, region, or component or intervening layers, regions, or components may be present therebetween. For example, it will be understood that when a layer, region, or component is referred to as being electrically connected to another layer, region, or component, the layer, region, or component can be directly or indirectly electrically connected to the other layer, region, or component,

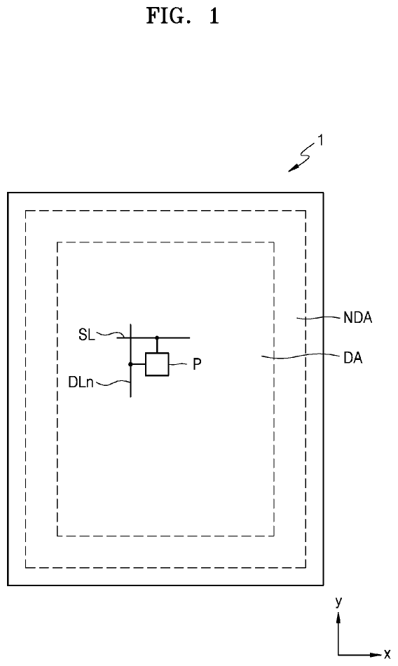

FIG. 1 is a schematic plan view of a display apparatus 1 according to an exemplary embodiment of the present invention.

Referring to FIG. 1, the display apparatus 1 includes a display area DA realizing an image and a non-display area NDA which does not realize an image. The non-display area NDA may at least partially surround the display area DA. The display apparatus 1 may provide an image by using light emitted from a plurality of pixels P arranged in the display area DA. Each pixel P may emit red, green, blue, or white light.

The display apparatus 1 is an apparatus displaying an image, and may include a portable mobile device, such as a game machine, a multimedia device, and a micro personal computer (PC). The display apparatus 1 to be described below may include a liquid-crystal display device, an electrophoretic display device, an inorganic EL display device (inorganic light-emitting display device), a field emission display device, a surface-conduction electron-emitter display device, a quantum dot display device, a plasma display device, a cathode ray display device, or the like. Hereinafter, although an organic light-emitting device is described as an example of the display apparatus 1 according to an exemplary embodiment of the present invention, various types of display apparatuses stated above may be used in one or more exemplary embodiments of the present invention.

The pixel P may be electrically connected to a scan line SL and a data line DLn. The scan line SL may extend in a first direction (for example, an x-direction), and the data line DLn may extend in a second direction (for example, a y-direction). The second direction (y) may be substantially perpendicular to the first direction (x)

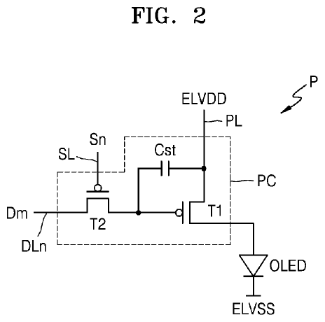

FIG. 2 is a circuit diagram of the pixel P included in a display apparatus according to an exemplary embodiment of the present invention.

Referring to FIG. 2, the pixel P may include a pixel circuit PC and an organic light-emitting diode OLED as a display element connected to the pixel circuit PC.

The pixel circuit PC may include a driving thin-film transistor T1, a switching thin-film transistor T2, and a storage capacitor Cst. Each pixel P may emit, for example, red, green, or blue light or may emit red, green, blue, or white light, through the organic light-emitting diode OLED.

The switching thin-film transistor T2 may be connected to the scan line SL and the data line DLn, and be configured to deliver, to the driving thin-film transistor T1, a data voltage input from the data line DLn based on a switching voltage input from the scan line SL. The storage capacitor Cst may be connected to the switching thin-film transistor T2 and a driving voltage line PL, and store a voltage corresponding to a difference between a voltage received from the switching thin-film transistor T2 and a first power supply voltage ELVDD supplied to the driving voltage line PL.

The driving thin-film transistor T1 may be connected to the driving voltage line PL and the storage capacitor Cst, and the driving thin-film transistor T1 may control a driving current flowing from the driving voltage line PL to the organic light-emitting diode OLED, which is in accordance with a voltage value stored in the storage capacitor Cst. The organic light-emitting diode OLED may emit light having a predetermined brightness according to the driving current. A common electrode (for example, a cathode) of the organic light-emitting diode OLED may receive a second power supply voltage ELVSS.

Although it is described with reference to FIG. 2 that the pixel circuit PC includes two thin-film transistors and one storage capacitor, the present invention is not limited thereto. The number of the thin-film transistors and the number of the storage capacitors may be variously changed according to the design of the pixel circuit PC. For example, the pixel circuit PC may further include one or more thin-film transistors in addition to the above-stated two thin-film transistors.

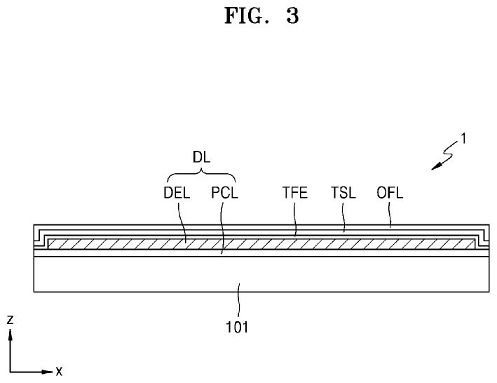

FIG. 3 is a schematic cross-sectional view of the display apparatus 1 according to an exemplary embodiment of the present invention.

Referring to FIG. 3, a display layer DL may be arranged on a substrate 101 of the display apparatus 1. The display layer DL may include a pixel-circuit layer PCL including a pixel circuit and insulating layers, and a display element layer DEL on the pixel-circuit layer PCL. The display element layer DEL includes a plurality of display elements.

The substrate 101 may include, for example, a glass or a polymer resin such as polyethersulfone, polyarylate, polyetherimide, polyethylene naphthalate, polyethylene terephthalate, polyphenylene sulfide, polyimide, polycarbonate (PC), cellulose triacetate (TAC), cellulose acetate propionate, or the like.

A barrier layer may be further included between the pixel-circuit layer PCL and the substrate 101. The barrier layer, which may prevent penetration of external foreign substances, may be a single layer structure or a multilayer structure including an inorganic material such as silicon nitride (SiNₓ, wherein x>0) and silicon oxide (SiOₓ, wherein x>0).

The display element layer DEL may include display elements, for example, the organic light-emitting diode OLED stated above. The pixel-circuit layer PCL may include a pixel circuit and insulating layers connected to each organic light-emitting diode OLED. The pixel-circuit layer PCL may include a plurality of transistors and storage capacitors, and insulating layers between the plurality of transistors and storage capacitors.

The display elements may be covered by an encapsulation member such as a thin-film encapsulation layer TFE. The thin-film encapsulation layer TFE may include at least one inorganic encapsulation layer and at least one organic encapsulation layer, which cover the display element layer DEL. The inorganic encapsulation layer may include at least one inorganic material such as aluminum oxide, titanium oxide, tantalum oxide, hafnium oxide, zinc oxide, silicon oxide, silicon nitride, and silicon oxynitride. The organic encapsulation layer may include a polymer-based material. The polymer-based material may include, for example, an acrylic resin, an epoxy resin, polyimide, polyethylene, or the like. In an exemplary embodiment of the present invention, the organic encapsulation layer may include an acrylate.

An input sensing unit TSL including touch electrodes may be arranged on the thin-film encapsulation layer TFE, and an optical functional layer OFL may be arranged on the input sensing unit TSL. The input sensing unit TSL may obtain coordinate information according to an external input, for example, a touch event. The optical functional layer OFL may reduce reflectance of light (e.g., external light) incident from the outside toward the display apparatus 1, and/or increase color purity of light emitted from the display apparatus 1. In an exemplary embodiment of the present invention, the optical functional layer OFL may include a retarder and a polarizer. For example, the retarder may be a film type or a liquid-crystal coating type, and may include a λ/2 retarder and/or a λ/4 retarder. For example, the polarizer may also be a film type or a liquid-crystal coating type. The film-type polarizer may include, for example, a stretch-type synthetic resin film, and the liquid-crystal-coating-type polarizer may include liquid crystals in a predetermined arrangement. For example, the retarder and the polarizer may further include a protective film.

In an exemplary embodiment of the present invention, the optical functional layer OFL may include a black matrix and color filters. The color filters may be arranged to correspond to a color of light emitted from each of the pixels of the display apparatus 1. Each of the color filters may include red, green, or blue pigments or dyes. In addition, each of the color filters may further include quantum dots in addition to the pigments or dyes stated above. In addition, some of the color filters may not include the pigments or dyes stated above and may include scattering particles such as titanium oxide.

In an exemplary embodiment of the present invention, the optical functional layer OFL may include a destructive interference structure. The destructive interference structure may include a first reflective layer and a second reflective layer arranged on different layers. First reflected light and second reflected light respectively reflected from the first reflective layer and the second reflective layer may destructively interfere, and thus, the reflectance of external light may be reduced.

An adhesive member may be arranged between the input sensing unit TSL and the optical functional layer OFL. As the adhesive member, a general adhesive member known in the related art may be employed without limitation. The adhesive member may include a pressure sensitive adhesive (PSA).

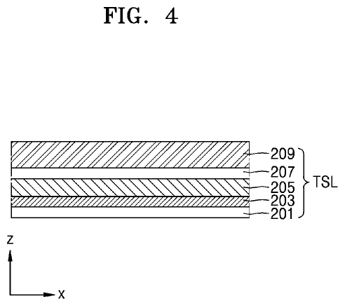

FIG. 4 is a cross-sectional view illustrating a stacked structure of the input sensing unit TSL according to an exemplary embodiment of the present invention.

Referring to FIG. 4, the input sensing unit TSL may include at least one inorganic film and a sensing electrode.

Insulating layers and conductive layers may be alternately stacked in the input sensing unit TSL. In an exemplary embodiment of the present invention, the input sensing unit TSL may include a first insulating layer 201, a first conductive layer 203, a second insulating layer 205, a second conductive layer 207, and a third insulating layer 209. The first conductive layer 203 and the second conductive layer 207 may be connected by a contact hole. The sensing electrode may include at least one of the first conductive layer 203 or the second conductive layer 207.

The first conductive layer 203 or the second conductive layer 207 may include a metal layer or a transparent conductive layer. The metal layer may include, for example, molybdenum (Mo), mendelevium (Md), silver (Ag), titanium (Ti), copper (Cu), aluminum (Al), and alloys thereof. The transparent conductive layer may include a transparent conductive oxide such as indium tin oxide (ITO), indium zinc oxide (IZO), indium tin zinc oxide (ITZO), or the like. In addition, the transparent conductive layer may include a conductive polymer such as poly(3,4-ethylenedioxythiophene) (PEDOT), metal nanowires, graphene, or the like.

The first conductive layer 203 or the second conductive layer 207 may be a single layer or a multilayer structure. A single layer first conductive layer 203 or single layer second conductive layer 207 may include the metal layer or the transparent conductive layer, and materials of the metal layer and the transparent conductive layer are as described above. One of the first conductive layer 203 and the second conductive layer 207 may include a single layer of the metal layer. One of the first conductive layer 203 and the second conductive layer 207 may include a multilayer of the metal layer. The multilayer of the metal layer may include, for example, three layers of a titanium layer/aluminum layer/titanium layer, or two layers of a molybdenum layer/mendelevium layer. In addition, the multilayer of the metal layer may include the metal layer and the transparent conductive layer. The first conductive layer 203 and the second conductive layer 207 may have different stacked structures from each other or the same stacked structure. For example, the first conductive layer 203 may include the metal layer, and the second conductive layer 207 may include the transparent conductive layer. In addition, the first conductive layer 203 and the second conductive layer 207 may include the same metal layer.

The materials of the first conductive layer 203 and the second conductive layer 207 and an arrangement of sensing electrodes included in the first conductive layer 203 and the second conductive layer 207 may be determined by considering the sensing sensitivity. Resistive-capacitive (RC) delay may affect the sensing sensitivity. Since the sensing electrodes including the metal layer have a smaller resistance compared to the sensing electrodes including the transparent conductive layer, a RC value may be reduced, and thus, the charging time of a capacitor provided between the sensing electrodes may be reduced. A user may not view the sensing electrodes including the transparent conductive layer compared to the sensing electrodes including the metal layer, and an input area of the sensing electrodes including the transparent conductive layer may be increased to increase the capacitance.

Each of the first insulating layer 201, the second insulating layer 205, and the third insulating layer 209 may include an inorganic insulating material or/and an organic insulating material. The inorganic insulating material may include, for example, silicon oxide, silicon nitride, silicon oxynitride, or the like, and the organic insulating material may include a polymer organic material. In an exemplary embodiment of the present invention, the first insulating layer 201 may be omitted.

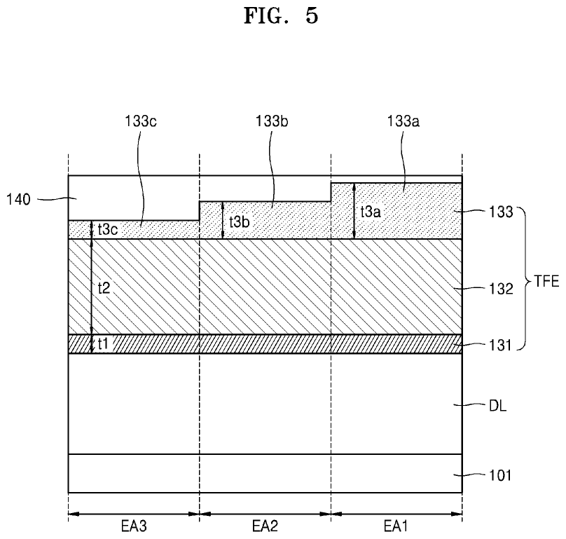

FIG. 5 is a schematic cross-sectional view of a portion of a display apparatus according to an exemplary embodiment of the present invention. In FIG. 5, the same reference numerals as those in FIG. 3 may refer to the same members, and redundant descriptions thereof may be omitted.

Referring to FIG. 5, the display layer DL and the thin-film encapsulation layer TFE may be arranged on the substrate 101. In an exemplary embodiment of the present invention, the display layer DL may include a first emission area EA1, a second emission area EA2, and a third emission area EA3.

Each of the first emission area EA1, the second emission area EA2, and the third emission area EA3 may emit light having different wavelengths from each other. For example, the first emission area EA1 may emit red light, the second emission area EA2 may emit blue light, and the third emission area EA3 may emit green light. In an exemplary embodiment of the present invention, a centroid wavelength of light emitted from the first emission area EA1 may be about 700 nm, a centroid wavelength of light emitted from the second emission area EA2 may be about 470 nm, and a centroid wavelength of light emitted from the third emission area EA3 may have a value between about 470 nm to about 700 nm. Hereinafter, a case where the first emission area EA1 emits red light, the second emission area EA2 emits blue light, and the third emission area EA3 emits green light will be mainly described.

The thin-film encapsulation layer TFE may include at least one inorganic encapsulation layer and at least one organic encapsulation layer which may be alternately stacked. In an exemplary embodiment of the present invention, the thin-film encapsulation layer TFE may include a first inorganic encapsulation layer 131, an organic encapsulation layer 132, and a second inorganic encapsulation layer 133. In an exemplary embodiment of the present invention, the thin-film encapsulation layer TFE may include a first inorganic encapsulation layer, a first organic encapsulation layer, a second inorganic encapsulation layer, a second organic encapsulation layer, and a third inorganic encapsulation layer. Hereinafter, for convenience of explanation, a case where the thin-film encapsulation layer TFE includes the first inorganic encapsulation layer 131, the organic encapsulation layer 132, and the second inorganic encapsulation layer 133 will be mainly described.

According to the multilayer structure, even when cracks occur in the thin-film encapsulation layer TFE, the thin-film encapsulation layer TFE may prevent the cracks from connecting between the first inorganic encapsulation layer 131 and the organic encapsulation layer 132 or between the organic encapsulation layer 132 and the second inorganic encapsulation layer 133. Accordingly, the formation of a path of a crack, through which external moisture or oxygen, or the like may penetrate into the display layer DL, may be prevented or minimized.

In an exemplary embodiment of the present invention a refractive index of the at least one inorganic encapsulation layer may be greater than a refractive index of the at least one organic encapsulation layer. For example, a refractive index of the first inorganic encapsulation layer 131 may be greater than a refractive index of the organic encapsulation layer 132, and a refractive index of the second inorganic encapsulation layer 133 may be greater than the refractive index of the organic encapsulation layer 132. For example, the refractive index of the organic encapsulation layer 132 may be about 1.45 to about 1.55. For example, the refractive indices of the first inorganic encapsulation layer 131 and the second inorganic encapsulation layer 133 may each be 1.55 or more. For example, the refractive index of the first inorganic encapsulation layer 131 may be about 1.55 to about 1.85. The refractive index of the second inorganic encapsulation layer 133 may be about 1.7 to about 2.1. Preferably, the refractive index of the second inorganic encapsulation layer 133 may be about 1.8 to about 2.1.

In an exemplary embodiment present invention, a thickness t2 of the organic encapsulation layer 132 may be greater than a thickness t1 of the first inorganic encapsulation layer 131 and/or a thickness of the second inorganic encapsulation layer 133. For example, the thickness t2 of the organic encapsulation layer 132 may be about 3 μm to about 15 μm. For example, the thickness t2 of the organic encapsulation layer 132 may be about 8.8 μm. A thickness t1 of the first inorganic encapsulation layer 131 may be about 0.5 μm to about 0.5 μm.

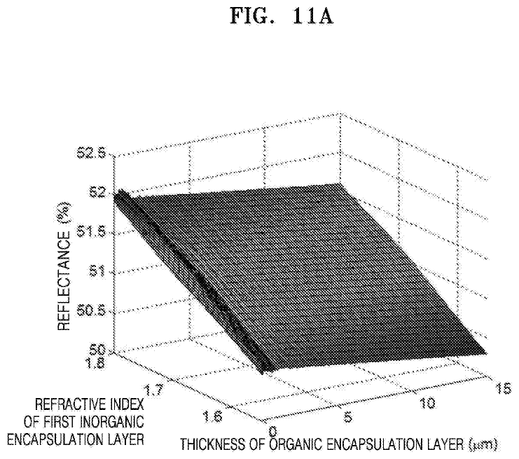

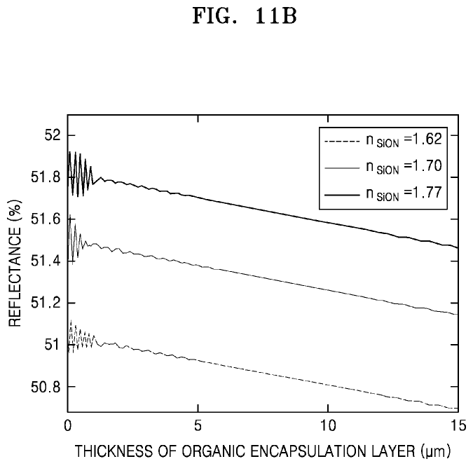

The thickness t1 and the refractive index of the first inorganic encapsulation layer 131, the thickness t2 and the refractive index of the organic encapsulation layer 132, and the refractive index of the second inorganic encapsulation layer 133 may be values for minimizing the reflectance of external light. This will be described below with reference to FIGS. 11A and 11B.

The thickness of the second inorganic encapsulation layer 133 may vary according to emission areas of the display layer DL emitting different light. In an exemplary embodiment of the present invention, a first thickness t3a of a first encapsulation portion 133a corresponding to the first emission area EA1 may be different from a second thickness t3b of a second encapsulation portion 133b corresponding to the second emission area EA2. In addition, the first thickness t3a and the second thickness t3b may be different from a third thickness t3c of a third encapsulation portion 133c corresponding to the third emission area EA3. For example, the first thickness t3a may be greater than the second thickness t3b. In addition, the second thickness t3b may be greater than the third thickness t3c. For example, the first thickness t3a may be about 0.8 μm, the second thickness t3b may be about 0.75 μm, and the third thickness t3c may be about 0.7 μm. The first thickness t3a, the second thickness t3b, and the third thickness t3c may be determined by considering the refractive index and the thickness t1 of the first inorganic encapsulation layer 131, the refractive index and the thickness t2 of the organic encapsulation layer 132, and the refractive index of the second inorganic encapsulation layer 133.

In an exemplary embodiment of the present invention, the second inorganic encapsulation layer 133 may have a staircase shape.

In an exemplary embodiment of the present invention, a planarization film 140 may be further included on the thin-film encapsulation layer TFE. The planarization film 140 may be arranged on the second inorganic encapsulation layer 133 having different thicknesses. For example, the planarization film 140 may have a shape that corresponds to the shape of the second inorganic encapsulation layer 133. In an exemplary embodiment of the present invention, the planarization film 140 may be arranged on the second encapsulation portion 133b or the third encapsulation portion 133c and may not be arranged on the first encapsulation portion 133a, In this case, an upper surface of the first encapsulation portion 133a and an upper surface of the planarization film 140 may be included in the same plane.

The planarization film 140 may relieve stress in the second inorganic encapsulation layer 133 and planarize an uneven surface of the second inorganic encapsulation layer 133. The planarization film 140 may include various organic materials such as an epoxy-based resin, an acrylic-based resin, a polyimide-based resin, or the like. A refractive index of the planarization film 140 may be about 1.55. Accordingly, the refractive index of the planarization film 140 may be less than the refractive index of the second inorganic encapsulation layer 133.

As described above, the second inorganic encapsulation layer 133 having different thicknesses corresponding to the first emission area. EA1 to the third emission area EA3 may be used to reduce a difference in reflection of external light.

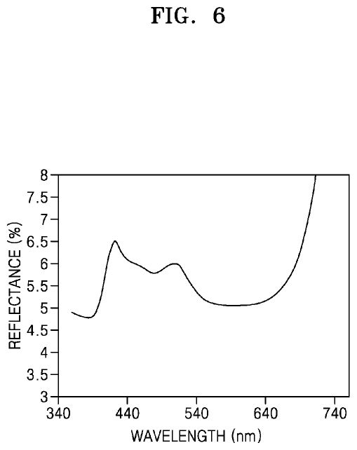

FIG. 6 illustrates a simulation result of a comparative example for comparing with an exemplary embodiment of the present invention.

In particular, FIG. 6 illustrates a simulation result regarding wavelengths of light and an overall reflectance in a comparative example in which the second inorganic encapsulation layer 133 has a constant thickness of 0.7 μm.

When the second inorganic encapsulation layer 133 has the same thickness corresponding to the first emission area EA1 to the third emission area EA3, the overall reflectance according to wavelengths of light in the thin-film encapsulation layer TFE may be different depending on a wavelength of light emitted from each emission area and a degree of absorption of external light in each emission layer to be described below. For example, a reflectance in the first emission area. EA1 emitting red light may be different from a reflectance in the second emission area EA2 emitting blue light. This is because a wavelength of red light and a wavelength of blue light are different and the degree of absorption of external light in each light emitting layer is different. Accordingly, a reflectance may be different according to each emission area.

In the present embodiment, a difference in the overall reflectance may be reduced by adjusting the thicknesses of the second inorganic encapsulation layer 133 according to light emitting areas emitting light having different wavelengths.

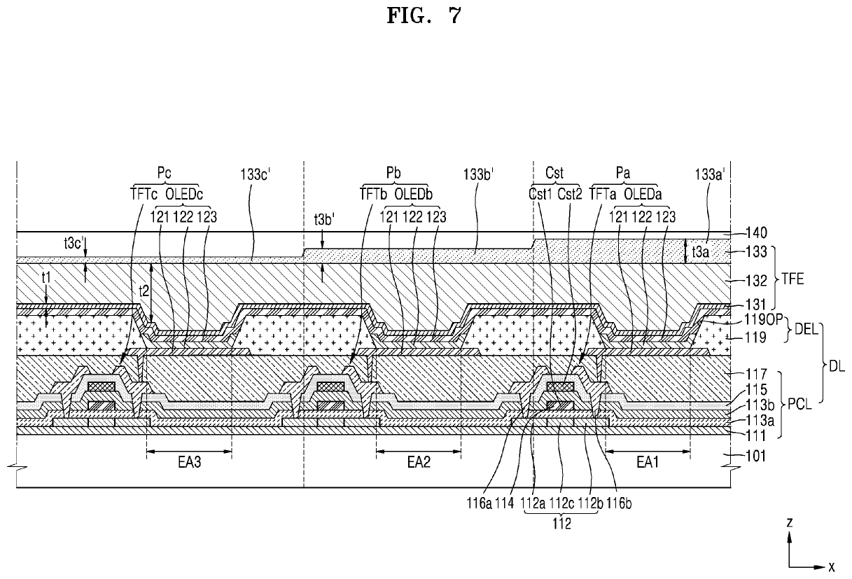

FIG. 7 is a schematic cross-sectional view of a display layer DL and a thin-film encapsulation layer TFE of a display apparatus according to an exemplary embodiment of the present invention.

Referring to FIG. 7, the display layer DL and the thin-film encapsulation layer TFE may be arranged on the substrate 101. The display layer DL may include a pixel-circuit layer PCL and a display element layer DEL. Hereinafter, a stacked structure of the pixel-circuit layer PCL and the display element layer DEL will be described in detail with reference to FIG. 7.

The pixel-circuit layer PCL is arranged on the substrate 101. FIG. 7 illustrates that the pixel-circuit layer PCL includes a buffer layer 111 arranged below or/and above a thin-film transistor and components of the thin-film transistor. The pixel-circuit layer PCL further includes a first gate insulating layer 113a, a second gate insulating layer 113b, an interlayer insulating layer 115, and a planarization insulating layer 117. The thin-film transistor may include a first thin-film transistor TFTa, a second thin-film transistor TFTb, and a third thin-film transistor TFTc.

Hereinafter, since structures of the second thin-film transistor TFTb and the third thin-film transistor TFTc are the same as that of the first thin-film transistor TFTa, the first thin-film transistor TFTa will be mainly described and detailed descriptions of the second thin-film transistor TFTb and the third thin-film transistor TFTc may be omitted.

The buffer layer 111 may include an inorganic insulating material such as silicon nitride, silicon oxynitride, and silicon oxide, and may include a single layer or a multilayer, each including the above-stated inorganic insulating material.

The first thin-film transistor TFTa may include a semiconductor layer 112, and the semiconductor layer 112 may include polysilicon. In addition, the semiconductor layer 112 may include amorphous silicon, an oxide semiconductor, an organic semiconductor, or the like. The semiconductor layer 112 may include a channel area 112c, a drain area 112a and a source area 112b respectively arranged on opposing sides of the channel area 112c. A gate electrode 114 may overlap the channel area 112c.

The gate electrode 114 may include a low-resistance metal material. The gate electrode 114 may include a conductive material including, for example, molybdenum (Mo), aluminum (Al), copper (Cu), titanium (Ti), or the like, and may include a single layer or a multilayer, each including the above material.

The first gate insulating layer 113a between the semiconductor layer 112 and the gate electrode 114 may include an inorganic insulating material such as silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), zinc oxide (ZnO₂), or the like.

The second gate insulating layer 113b may cover the gate electrode 114. Similar to the first gate insulating layer 113a, the second gate insulating layer 113b may include an inorganic insulating material such as silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), zinc oxide (ZnO₂), or the like.

An upper electrode Cst2 of a storage capacitor Cst may be arranged on the second gate insulating layer 113b. The upper electrode Cst2 may overlap the gate electrode 114 which is below the upper electrode Cst2. The gate electrode 114 and the upper electrode Cst2 overlapping each other, with the second gate insulating layer 113b arranged between the gate electrode 114 and the upper electrode Cst2, may form the storage capacitor Cst. For example, the gate electrode 114 may function as a lower electrode Cst1 of the storage capacitor Cst.

As such, the storage capacitor Cst and the first thin-film transistor TFTa may overlap each other. In an exemplary embodiment of the present invention, the storage capacitor Cst may not overlap the first thin-film transistor TFTa.

The upper electrode Cst2 may include, for example, aluminum (Al), platinum (Pt), palladium (Pd), silver (Ag), magnesium (Mg), gold (Au), neodymium (Nd), iridium (1r), chromium (Cr), nickel (Ni), calcium (Ca), molybdenum (Mo), titanium (Ti), tungsten (W), and/or copper (Cu), and may include a single layer or a multilayer, each including the above materials.

The interlayer insulating layer 115 may cover the upper electrode Cst2. The interlayer insulating layer 115 may include, for example, silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), zinc oxide (ZnO₂), or the like. The interlayer insulating layer 115 may include a single layer or a multilayer, each including the above-stated inorganic insulating materials.

Each of a drain electrode 116a and a source electrode 116b may be located on the interlayer insulating layer 115. The drain electrode 116a and the source electrode 116b may include a material having relatively good conductivity. The drain electrode 116a and the source electrode 116b may include a conductive material including, for example, molybdenum (Mo), aluminum (Al), copper (Cu), titanium (Ti), or the like, and may include a single layer or a multilayer, each including the above material. In an exemplary embodiment of the present invention, the drain electrode 116a and the source electrode 116b may include a multilayer structure of Ti/Al/Ti.

The planarization insulating layer 117 may include an organic insulating layer. The planarization insulating layer 117 may include a general polymer such as poly(methyl methacrylate) (PMMA) or polystyrene (PS), a polymer derivative having a phenol group, an acrylic polymer, an imide polymer, an aryl ether polymer, an amide polymer, a fluorine polymer, a p-xylene polymer, a vinyl alcohol polymer, and a mixture thereof.

The display element layer DEL is arranged on the pixel-circuit layer PCL. The display element layer DEL may include a first organic light-emitting diode OLEDa, a second organic light-emitting diode OLEDb, and a third organic light-emitting diode OLEDc, and a pixel electrode 121 of the first organic light-emitting diode OLEDa may be electrically connected to the first thin-film transistor TFTa through a contact hole of the planarization insulating layer 117. In addition, pixel electrodes 121 of the second organic light-emitting diode OLEDb and the third organic light-emitting diode OLEDc may be respectively electrically connected to the second thin-film transistor TFTb and the third thin-film transistor TFTc through contact holes of the planarization insulating layer 117.

The pixel P described with reference to FIG. 2 may correspond to each of a first pixel Pa, a second pixel Pb, and a third pixel Pc. For example, the first pixel Pa may include the first organic light-emitting diode OLEDa and the first thin-film transistor TFTa. In an exemplary embodiment of the present invention, the second pixel Pb may include the second organic light-emitting diode OLEDb and the second thin-film transistor TFTb. In an exemplary embodiment of the present invention, the third pixel Pc may include the third organic light-emitting diode OLEDc and the third thin-film transistor TFTc.

In an exemplary embodiment of the present invention, the first organic light-emitting diode OLEDa may emit red light. The second organic light-emitting diode OLEDb may emit blue light. The third organic light-emitting diode OLEDc may emit green light. In an exemplary embodiment of the present invention, a centroid wavelength of light emitted from the first organic light-emitting diode OLEDa may be about 700 nm, a centroid wavelength of light emitted from the second organic light-emitting diode OLEDb may be about 470 nm, and a centroid wavelength of light emitted from the third organic light-emitting diode OLEDc may have a value between about 470 nm to about 700 nm.

Hereinafter, since a structure of the second organic light-emitting diode OLEDb and a structure of the third organic light-emitting diode OLEDc are the same as a structure of the first organic light-emitting diode OLEDa, the structure of the first organic light-emitting diode OLEDa will be mainly described, and detailed descriptions of the structure of the second organic light-emitting diode OLEDb and the structure of the third organic light-emitting diode OLEDc may be omitted.

The pixel electrode 121 may include a conductive oxide material such as indium tin oxide (ITO), indium zinc oxide (IZO), zinc oxide (ZnO), indium oxide (In₂O₃), indium gallium oxide (IGO), and/or aluminum zinc oxide (AZO). In an exemplary embodiment of the present invention, the pixel electrode 121 may include a reflective film including silver (Ag), magnesium (Mg), aluminum (Al), platinum (Pt), palladium (Pd), gold (Au), nickel (Ni), neodymium (Nd), iridium (Jr), chromium (Cr), or a compound thereof. In an exemplary embodiment of the present invention, the pixel electrode 121 may further include a film including ITO, IZO, ZnO, or In₂O₃ above/below the reflective film.

A pixel defining film 119 having an opening portion 1190P exposing a central portion of the pixel electrode 121 is arranged on the pixel electrode 121. The pixel defining film 119 may include an organic insulating material and/or an inorganic insulating material. The opening portion 1190P may provide an emission area of light emitted from the first organic light-emitting diode OLEDa (hereinafter, referred to as a first emission area EA1), For example, a width of the opening portion 1190P may correspond to a width of the first emission area EA1. For example, the width of the opening portion 1190P may be a size at which the central portion of the pixel electrode 121 is exposed. Similarly, other opening portions 1190P may be provided in the pixel defining film 119 to provide an emission area of light emitted from the second organic light-emitting diode OLEDb (hereinafter, referred to as a second emission area EA2) and an emission area of light emitted from the third organic light-emitting diode OLEDc (hereinafter, referred to as a third emission area EA3).

An emission layer 122 may be arranged in the opening portion 1190P of the pixel defining film 119. The emission layer 122 may include, for example, a polymer organic material or a low-molecular-weight organic material which emits light of a color. In addition, a first functional layer and a second functional layer may be respectively arranged below and above the emission layer 122. The first functional layer may include a hole transport layer (HTL) or an HTL and a hole injection layer (HIL). The second functional layer, as a component arranged above the emission layer 122, is optional. The second functional layer may include an electron transport layer (ETL) and/or an electron injection layer (EIL). Similar to a common electrode 123 to be described later, the first functional layer and/or the second functional layer may be a common layer entirely covering the substrate 101.

The common electrode 123 may include a conductive material having a low work function. For example, the common electrode 123 may include a (semi)transparent layer including, for example, silver (Ag), magnesium (Mg), aluminum (Al), platinum (Pt), palladium (Pd), gold (Au), nickel (Ni), neodymium (Nd), iridium (Ir), chromium (Cr), lithium (Li), calcium (Ca), an alloy thereof, or the like. In addition, the common electrode 123 may further include a layer such as ITO, IZO, ZnO, or In₂O₃ above the (semi)transparent layer including the above-stated materials.

As described above, a thin-film encapsulation layer TFE may include at least one inorganic encapsulation layer and at least one organic encapsulation layer which may be alternately stacked. In an exemplary embodiment of the present invention, the thin-film encapsulation layer TFE may include a first inorganic encapsulation layer 131, an organic encapsulation layer 132, and a second inorganic encapsulation layer 133.

The second inorganic encapsulation layer 133 may include a first portion 133a′, a second portion 133b′, and a third portion 133e. The first portion 133a′ may be a portion of the second inorganic encapsulation layer 133 corresponding to the first organic light-emitting diode OLEDa. The second portion 133b′ may be a portion of the second inorganic encapsulation layer 133 corresponding to the second organic light-emitting diode OLEDb. The third portion 133c′ may be a portion of the second inorganic encapsulation layer 133 corresponding to the third organic light-emitting diode OLEDc.

In an exemplary embodiment of the present invention, a refractive index of the at least one inorganic encapsulation layer may be greater than a refractive index of the at least one organic encapsulation layer. In an exemplary embodiment of the present invention, a refractive index of the organic encapsulation layer 132 may be about 1.45 to about 1.55. Refractive indices of the first inorganic encapsulation layer 131 and the second inorganic encapsulation layer 133 may be 1.55 or more. For example, the refractive index of the first inorganic encapsulation layer 131 may be about 1.55 to about 1.85. The refractive index of the second inorganic encapsulation layer 133 may be about 1.7 to about 2.1. Preferably, the refractive index of the second inorganic encapsulation layer 133 may be about 1.8 to about 2.1.

A thickness t2 of the organic encapsulation layer 132 may be greater than a thickness t1 of the first inorganic encapsulation, layer 131 and/or a thickness of the second inorganic encapsulation layer 133. Herein, the thickness t2 of the organic encapsulation layer 132 may be an average value of a thickness from the pixel defining film 119 to the second inorganic encapsulation layer 133 and a thickness from the common electrode 123 corresponding to an emission area to the second inorganic encapsulation layer 133. For example, the thickness t1 of the first inorganic encapsulation layer 131 may be about 0.5 μm to about 1.5 μm. The thickness t2 of the organic encapsulation layer 132 may be about 3 μm to about 15 μm. For example, the thickness t2 of the organic encapsulation layer 132 may be about 8.8 μm.

The thickness t2 of the second inorganic encapsulation layer 133 may vary according to organic light-emitting diodes emitting different light. The third portion 133c′ may be a portion of the second inorganic encapsulation layer 133 corresponding to the third organic light-emitting diode OLEDc. A first thickness t3a′ of the first portion 133a′ may be different from a second thickness t3b′ of the second portion 133b′. In addition, the first thickness t3a′ and the second thickness t3b′ may be different from a third thickness t3c′ of the third portion 133e. For example, the first thickness t3a′ may be greater than the second thickness t3b″. The second thickness t3b′ may be greater than the third thickness t3e. For example, the first thickness t3a′ may be about 0.8 μm, the second thickness t3b′ may be about 0.75 μm, and the third thickness t3c′ may be about 0.7 μm. The first thickness t3a′, the second thickness t3b′, and the third thickness t3c′ may be determined by considering all of the refractive index and thickness t1 of the first inorganic encapsulation layer 131, the refractive index and thickness t2 of the organic encapsulation layer 132, and the refractive index of the second inorganic encapsulation layer 133.

In an exemplary embodiment of the present invention, a planarization film 140 may be further included on the thin-film encapsulation layer TFE. The planarization film 140 may be arranged on the second inorganic encapsulation layer 133 having different thicknesses. In an exemplary embodiment of the present invention, the planarization film 140 may be arranged on the second portion 133b′ or the third portion 133c′ and may not be arranged on the first portion 133a′. In this case, an upper surface of the first portion 133a′ and an upper surface of the planarization film 140 may be included on the same plane. For example, the planarization film 140 may planarize an upper surface of the second inorganic encapsulation layer 133.

In the present embodiment, a difference in the overall reflectance may be reduced by adjusting the thicknesses of the second inorganic encapsulation layer 133 according to organic light-emitting diodes emitting light having different wavelengths.

In an exemplary embodiment of the present invention, in a case where the refractive index of the first inorganic encapsulation layer 131 is about 1.55 to about 1.85 and the thickness t1 of the first inorganic encapsulation layer 131 is about 0.5 μm to about 1.5 μm, reflectance of external light incident to the thin-film encapsulation layer TFE may be reduced. For example, the refractive index of organic encapsulation layer 132 may be about 1.45 to about 1.55, and the thickness t2 of the organic encapsulation layer 132 may be about 3 μm to about 15 μm. In addition, the refractive index of the second inorganic encapsulation layer 133 may be about 1.7 to about 2.1. Preferably, the refractive index of the second inorganic encapsulation layer 133 may be about 1.8 to about 2.1.

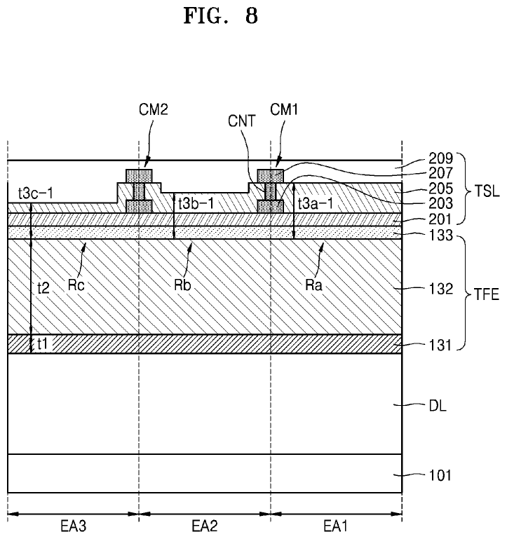

FIG. 8 is a schematic cross-sectional view of a portion of a display apparatus according to an exemplary embodiment of the present invention. In FIG. 8, the same reference numerals as those in FIG. 5 may refer to the same members, and redundant descriptions thereof may be omitted.

Referring to AG. 8, the display layer DL and the thin-film encapsulation layer TFE may be arranged on the substrate 101. The display layer DL may include display elements, each of which emits light of a different color from each other. In an exemplary embodiment of the present invention, the display layer DL may include the first emission area EA1, the second emission area EA2, and the third emission area EA3, as areas emitting light, and each of the first, second and third emission areas EA1, EA2 and EA3 emits a different color of light from each other.

The input sensing unit TSL may be arranged on the thin-film encapsulation layer TFE. The input sensing unit TSL may include at least one inorganic film and a sensing electrode. The input sensing unit TSL may include the first insulating layer 201, the first conductive layer 203, the second insulating layer 205, the second conductive layer 207, and the third insulating layer 209. The sensing electrode may include at least one of the first conductive layer 203 or the second conductive layer 207. Hereinafter, the sensing electrode will be mainly described in detail with reference to a case in which the sensing electrodes includes the first conductive layer 203 and the second conductive layer 207 connected to the second insulating layer 205 through a contact hole CNT.

In an exemplary embodiment of the present invention, the second inorganic encapsulation layer 133 may be connected to the first insulating layer 201. In an exemplary embodiment of, the present invention, when the first insulating layer 201 is omitted, the second inorganic encapsulation layer 133 may be connected to the second insulating layer 205. In this case, the second inorganic encapsulation layer 133, the first insulating layer 201, and the second insulating layer 205 may include the same material. The first insulating layer 201 and the second insulating layer 205 may include an inorganic insulating material.

The first conductive layer 203 may be arranged on the first insulating layer 201, and the second insulating layer 205 may be arranged to cover the first conductive layer 203. The second insulating layer 205 may have different thicknesses according to respective emission areas. For example, a thickness of the second insulating layer 205 corresponding to the first emission area EA1 may be different from a thickness of the second insulating layer 205 corresponding to the second emission area EA2. In addition, a thickness of the second insulating layer 205 corresponding to the third emission area EA3 may be different from the thickness of the second insulating layer 205 corresponding to the first emission area EA1 and/or the second emission area EA2. In an exemplary embodiment of the present invention, the second insulating layer 205 may not be arranged in the third emission area EA3.

The second insulating layer 205 may include a contact hole CNT, and the second conductive layer 207 may be connected to the first conductive layer 203 through the contact hole CNT.

The third insulating layer 209 may be arranged to cover the second conductive layer 207. In an exemplary embodiment of the present invention, the third insulating layer 209 may planarize an uneven surface. The third insulating layer 209 may include an organic insulating material, for example, a polymer organic material. A refractive index of the third insulating layer 209 may be about 1.55. In an exemplary, the third insulating layer 209 may be connected to the first insulating layer 201. For example, the first insulating layer 201 may be directly connected to the third insulating layer 209.

According to the emission areas emitting different colors light from each other, a total thickness of the second inorganic encapsulation layer 133, the first insulating layer 201, and the second insulating layer 205 may be different. In an exemplary embodiment of the present invention, a first area Ra may be an area including the second inorganic encapsulation layer 133, the first insulating layer 201, and the portion of the second insulating layer 205 that corresponds to the first emission area EA1. Further, a second area Rb may be an area including the second inorganic encapsulation layer 133, the first insulating layer 201, and the portion of the second insulating layer 205 that corresponds to the second emission area EA2. In this case, a thickness t3a-1 of the first area Ra may be different from a thickness t3b-1 of the second area Rb. In addition, a third area Rc may be an area including the second inorganic encapsulation layer 133, the first insulating layer 201, and the portion of the second insulating layer 205 that corresponds to the third emission area EA3. A thickness t3c-1 of the third area Rc may be different from the thickness t3a-1 of the first area Ra and the thickness t3b-1 of the second area Rb. For example, the thickness t3a-1 of the first area Ra may be greater than the thickness t3b-1 of the second area Rb. The thickness t3b-1 of the second area Rb may be greater than the thickness t3c-1 of the third area Rc. For example, the thickness t3a-1 of the first area Ra may be about 1 μm, the thickness t3b-1 of the second area Rb may be about 0.95 μm, and the thickness t3c-1 of the third area. Rc may be about 0.9 μm. The thickness t3a-1 of the first area Ra, the thickness t3b-1 of the second area Rb, and the thickness t3c-1 of the third area Rc are values set based on all of the refractive index and the thickness t1 of the first inorganic encapsulation layer 131 the refractive index and the thickness t2 of the organic encapsulation layer 132, and the refractive indices of the second inorganic encapsulation layer 133 and the insulating layers of the input sensing unit TSL.

The sensing electrode may be arranged between the emission areas different from each other. In an exemplary embodiment of the present invention, a first sensing electrode CM1 may be arranged between the first emission area EA1 and the second emission area EA2. For example, the first sensing electrode CM1 may be disposed at a boundary between the first emission area EA1 and the second emission area EA2. In addition, a second sensing electrode CM2 may be arranged between the second emission area EA2 and the third emission area EA3. For example, the second sensing electrode CM2 may be disposed at a boundary between the second emission area EA2 and the third emission area EA3. The first sensing electrode CM1 and/or the second sensing electrode CM2 may be arranged between the emission areas different from each other and may increase transmittance of light emitted from the display layer DL.

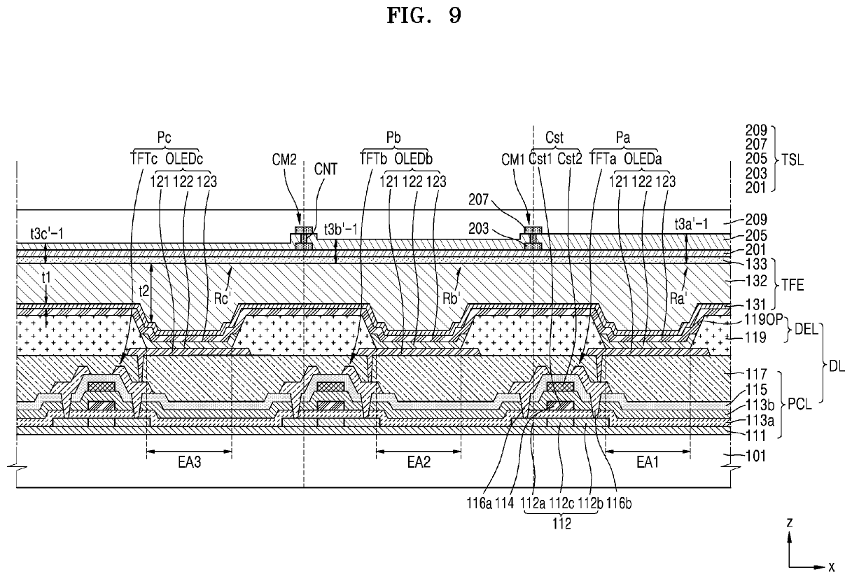

FIG. 9 is a schematic cross-sectional view of a display layer DL and a thin-film encapsulation layer TFE of a display apparatus according to an exemplary embodiment of the present invention. In FIG. 9, the same reference numerals as those in FIG. 7 may refer to the same members, and redundant descriptions thereof may be omitted.

Referring to FIG. 9, the display layer DL and the thin-film encapsulation layer TEE may be arranged on the substrate 101. The display layer DL may include the pixel-circuit layer PCL and the display element layer DEL.

In an exemplary embodiment of the present invention, the input sensing unit TSL may be arranged on the thin-film encapsulation layer TEE. The input sensing unit TSL may include at least one inorganic film and a sensing electrode. The input sensing unit TSL may include the first insulating layer 201, the first conductive layer 203, the second insulating layer 205, the second conductive layer 207, and the third insulating layer 209. The sensing electrode may include at least one of the first conductive layer 203 and/or the second conductive layer 207.

In an exemplary embodiment of the present invention, the second inorganic encapsulation layer 133 may be connected to the first insulating layer 201. In an exemplary embodiment of the present invention, when the first insulating layer 201 is omitted, the second inorganic encapsulation layer 133 may be connected to the second insulating layer 205. In this case, the second inorganic encapsulation layer 133, the first insulating layer 201, and the second insulating layer 205 may include the same material. The first insulating layer 201 and the second insulating layer 205 may include an inorganic insulating material.

The first conductive layer 203 may be arranged on the first insulating layer 201, and the second insulating layer 205 may be arranged to cover the first conductive layer 203. The second insulating layer 205 may have different thicknesses according to the respective organic light-emitting diode. For example, a thickness of a portion of the second insulating layer 205 corresponding to the first organic light-emitting diode OLEDa may be different from a thickness of a portion of the second insulating layer 205 corresponding to the second organic light-emitting diode OLEDb. In addition, a thickness of a portion of the second insulating layer 205 corresponding to the third organic light-emitting diode OLEDc may be different from the thickness of the portion of the second insulating layer 205 corresponding to the first organic light-emitting diode OLEDa and/or the thickness of the portion of the second insulating layer 205 corresponding to the second organic light-emitting diode OLEDb. In an exemplary embodiment of the present invention, the second insulating layer 205 may not be arranged above the third organic light-emitting diode OLEDc.

The second insulating layer 205 may include a contact hole CNT, and the second conductive layer 207 may be connected to the first conductive layer 203 through the contact hole CNT.

The third insulating layer 209 may be arranged to cover the second conductive layer 207. In an exemplary embodiment of the present invention, the third insulating layer 209 may planarize an uneven surface. The third insulating layer 209 may include an organic insulating material, for example, a polymer organic material. A refractive index of the third insulating layer 209 may be about 1.55. In an exemplary embodiment of the present invention, the third insulating layer 209 may be connected to the first insulating layer 201. For example, the first insulating layer 201 may be directly connected to the third insulating layer 209.

According to the organic light-emitting diodes emitting different colors of light from each other, a total thickness of the second inorganic encapsulation layer 133, the first insulating layer 201, and the second insulating layer 205 may be different. In an exemplary embodiment of the present invention, a first-first area Ra′ may be an area including the second inorganic encapsulation layer 133, the first insulating layer 201, and the portion of the second insulating layer 205 that corresponds to the first organic light-emitting diode OLEDa. In addition, a second-first area Rb′ may be an area including the second inorganic encapsulation layer 133, the first insulating layer 201, and the portion of the second insulating layer 205 that corresponds to the second organic light-emitting diode OLEDb. In this case, a thickness t3a′-1 of the first-first area Ra′ may be different from a thickness t3b′-1 of the second-first area Rb′. In addition, a third-first area Rc′ may be an area including the second inorganic encapsulation layer 133, the first insulating layer 201, and the portion of the second insulating layer 205 that corresponds to the third organic light-emitting diode OLEDc. A thickness t3c′-1 of the third-first area Rc′ may be different from the thickness t3a′-1 of the first-first area Ra′ and the thickness t3b′-1 of the second-first area Rb′. For example, the thickness t3a′-1 of the first-first area Ra′ may be greater than the thickness t3a′-1 of the second-first area Rb′. The thickness t3b′-1 of the second-first area Rb′ may be greater than the thickness t3c′-1 of the third-first area. Rc′. For example, the thickness t3a′-1 of the first-first area Ra′ may be about 1 μm, the thickness t3b′-1 of the second-first area Rb′ may be about 0.95 μm, and the thickness t3c′-1 of the third-first area Rc′ may be about 0.9 μm. The thickness t3a′-1 of the first-first area Ra′, the thickness t3b′-1 of the second-first area Rb′, and the thickness t3c′-1 of the third-first area Rc′ are values set based on all of the refractive index and the thickness t1 of the first inorganic encapsulation layer 131, the refractive index and the thickness t2 of the organic encapsulation layer 132, and the refractive indices of the second inorganic encapsulation layer 133 and the insulating layers of the input sensing unit TSL.

The sensing electrode may be arranged between different display elements. In an exemplary embodiment of the present invention, a first sensing electrode CM1 may be arranged between the first organic light-emitting diode OLEDa and the second organic light-emitting diode OLEDb. In addition, a second sensing electrode CM2 may be arranged between the second organic light-emitting diode OLEDb and the third organic light-emitting diode OLEDc. The first sensing electrode CM1 and/or the second sensing electrode CM2 may be arranged between different organic light-emitting diodes and may increase transmittance of light emitted from the organic light-emitting diodes.

In an exemplary embodiment of the present invention, the refractive index of the first inorganic encapsulation layer 131 may be about 1.55 to about 1.85, and the thickness t1 of the first inorganic encapsulation layer 131 may be about 0.5 μm to about 1.5 μm. In this case, reflectance of external light incident on the thin-film encapsulation layer TFE may be reduced. For example, the refractive index of organic encapsulation layer 132 may be about 1.45 to about 1.55, and the thickness t2 of the organic encapsulation layer 132 may be about 3 μm to about 15 μm. In addition, the refractive index of the second inorganic encapsulation layer 133 may be about 1.7 to about 2.1. Preferably, the refractive index of the second inorganic encapsulation layer 133 may be about 1.8 to about 2.1.

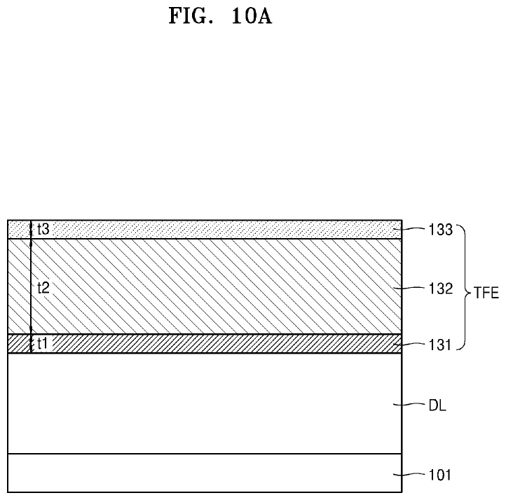

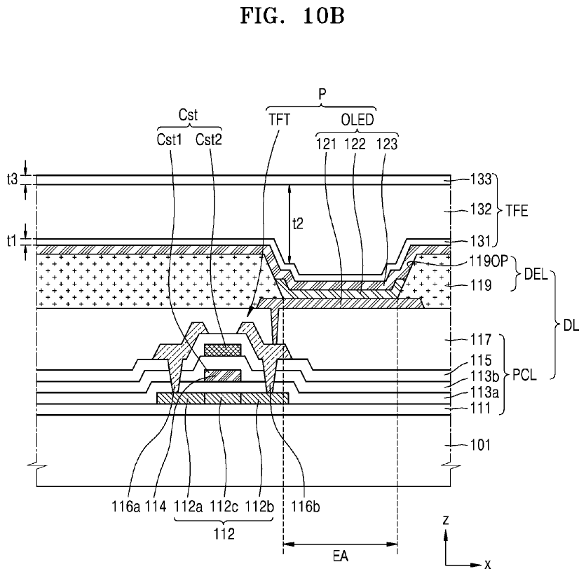

FIG. 10A is a schematic cross-sectional view of a portion of a display apparatus according to an exemplary embodiment of the present invention. FIG. 10B is a schematic cross-sectional view of a display layer DL and a thin-film encapsulation layer TFE of a display apparatus according to an exemplary embodiment of the present invention.

In FIGS. 10A and 10B, the display layer DL and the thin-film encapsulation layer TFE may be arranged on the substrate 101. The display layer DL may include display elements arranged in a display area. In an exemplary embodiment of the present invention, the display element may be an organic light-emitting diode OLED.

The thin-film encapsulation layer TFE may include at, least one inorganic encapsulation layer and at least one organic encapsulation layer. In an exemplary embodiment of the present invention, the thin-film encapsulation layer TFE may include a first inorganic encapsulation layer 131, an organic encapsulation layer 132, and a second inorganic encapsulation layer 133. In an exemplary embodiment of the present invention, the thin-film encapsulation layer TFE may include a first inorganic encapsulation layer, a first organic encapsulation layer, a second inorganic encapsulation layer, a second organic encapsulation layer, and a third inorganic encapsulation layer.

In an exemplary embodiment of the present invention, a refractive index of the organic encapsulation layer 132 may be less than a refractive index of the first inorganic encapsulation layer 131 and/or the second inorganic encapsulation layer 133. For example, the refractive index of the organic encapsulation layer 132 may be about 1.45 to about 1.55. Refractive indices of the first inorganic encapsulation layer 131 and the second inorganic encapsulation layer 133 may be about 1.55 or more. For example, the refractive index of the first inorganic encapsulation layer 131 may be about 1.55 to about 1.85. The refractive index of the second inorganic encapsulation layer 133 may be about 1.7 to about 2.1. Preferably, the refractive index of the second inorganic encapsulation layer 133 may be about 1.8 to about 2.1.

In an exemplary embodiment of the present invention, a thickness t2 of the organic encapsulation layer 132 may be greater than a thickness t1 of the first inorganic encapsulation layer 131 and/or a thickness t3 of the second inorganic encapsulation layer 133. Herein, the thickness t2 of the organic encapsulation layer 132 may be an average value of a thickness from the pixel defining film 119 to the second inorganic encapsulation layer 133 and a thickness from the common electrode 123 corresponding to an emission area EA to the second inorganic encapsulation layer 133. The thickness t2 of the organic encapsulation layer 132 may be about 3 μm to about 15 μm. The thickness t1 of the first inorganic encapsulation layer 131 may be about 0.5 μm to about 1.5 μm. The thickness of the second inorganic encapsulation layer 133 may be about 0.4 μm to about 1.5 μm. Preferably, the thickness of the second inorganic encapsulation layer 133 may be about 0.4 μm to about 1.2 μm.

External light may be incident on the thin-film encapsulation layer TFE in a direction of the display layer DL. Since the first inorganic encapsulation layer 131, the organic encapsulation layer 132, and the second inorganic encapsulation layer 133 may have different refractive indices, the external light may be reflected from each of a plane of incidence between the first inorganic encapsulation layer 131 and the organic encapsulation layer 132 and a plane of incidence between the organic encapsulation layer 132 and the second inorganic encapsulation layer 133. In this case, reflectance of the external light may be increased according to the refractive index and/or the thickness of each of the first inorganic encapsulation layer 131, the organic encapsulation layer 132, and the second inorganic encapsulation layer 133. In the present embodiment, the refractive indices and/or the thicknesses of the first inorganic encapsulation layer 131, the organic encapsulation layer 132, and the second inorganic encapsulation layer 133 may be adjusted as described above to reduce the reflectance of the external light.

FIG. 11A illustrates a simulation result showing a relationship between reflectance of light and a refractive index of a first inorganic encapsulation layer and a thickness of an organic encapsulation layer, according to an exemplary embodiment of the present invention. FIG. 11B illustrates a simulation result showing reflectance of external light according to a thickness of an organic encapsulation layer, according to an exemplary embodiment of the present invention.

Referring to FIGS. 11A and 11B, it can be seen that when the thickness of the organic encapsulation layer is about 3 μm or less, a reflectance value changes as the thickness of the organic encapsulation layer increases. However, when the thickness of the organic encapsulation layer is about 3 μm or more, the reflectance value is stabilized according to the thickness of the organic encapsulation layer. In addition, when the thickness of the organic encapsulation layer is about 15 μm or more, the cost and time of manufacturing a thin-film encapsulation layer increase and a thickness of the thin-film encapsulation layer becomes thicker, and thus, making a display apparatus thin and flexible may be difficult.

In addition, the reflectance value of external light may increase as the refractive index of the first inorganic encapsulation layer increases. When the refractive index of the first inorganic encapsulation layer is from about 1.55 to about 1.85 and the thickness of the organic encapsulation layer is about 3 μm, or more, the reflectance value may be stabilized.

As described above, according to an exemplary embodiment of the present invention, a difference in reflection of external light on a display element emitting light of different wavelengths may be reduced by varying a thickness of at least one inorganic encapsulation layer in a thin-film encapsulation layer corresponding to the display element.

In addition, according to an exemplary embodiment of the present invention, the reflection of the external light incident on a display apparatus may be reduced.

While the present invention has been described with reference to exemplary embodiments thereof, it will be understood by those of ordinary skill in the art that various changes in form and details may be made thereto without departing from the spirit and scope of the present invention.

What is claimed is:

1. A display apparatus comprising:
a substrate comprising a display area and a non-display area;
a display layer comprising a first display element and a second display element arranged in the display area; and
a thin-film encapsulation layer arranged to cover the display layer and comprising at least one organic encapsulation layer and at least one inorganic encapsulation layer, wherein the at least one organic encapsulation layer and the at least one inorganic encapsulation layer are alternately stacked,
wherein a refractive index of the at least one inorganic encapsulation layer greater than a refractive index of the at least one organic encapsulation layer, and
a thickness of a first portion of the at least one inorganic encapsulation layer corresponding to the first display element is different from a thickness of a second portion of the at least one inorganic encapsulation layer corresponding to the second display element.

2. The display apparatus of claim 1, wherein the at least one inorganic encapsulation layer of the thin-film encapsulation layer comprises a first inorganic encapsulation layer, and a second inorganic encapsulation layer, and the at least one organic encapsulation layer of the thin-film encapsulation layer comprises an organic encapsulation layer, wherein the first inorganic encapsulation layer, the organic encapsulation layer and the second inorganic encapsulation layer are stacked,
a first thickness of the second inorganic encapsulation layer corresponding to the first display element is different from a second thickness of the second inorganic encapsulation layer corresponding to the second display element.

3. The display apparatus of claim 2, wherein the first display element emits red light and the second display element emits green light, and
the first thickness is greater than the second thickness.

4. The display apparatus of claim 2, wherein the display layer further comprises a third display element, and
a third thickness of the second inorganic encapsulation layer corresponding to the third display element is different from the first thickness and the second thickness.

5. The display apparatus of claim 4, wherein the first display element emits red light, the second display element emits blue light, and the third display element emits green light,
the first thickness is greater than the second thickness, and
the second thickness is greater than the third thickness.

6. The display apparatus of claim 1, further comprising an input sensing unit arranged on the thin-film encapsulation layer and comprising a sensing electrode and at least one inorganic film,
wherein the at least one inorganic encapsulation layer is connected to the at least one inorganic film, and
a first total thickness of the first portion of the at least one inorganic encapsulation layer and the at least one inorganic film, each of which correspond to the first display element, is different from a second total thickness of the second portion of the at least one inorganic encapsulation layer and the at least one inorganic film, each of which correspond to the second display element.

7. The display apparatus of claim 6, wherein the at least one inorganic encapsulation layer of the thin-film encapsulation layer comprises a first inorganic encapsulation layer, and a second inorganic encapsulation layer, and the at least one organic encapsulation layer of the thin-film encapsulation layer comprises an organic encapsulation layer, wherein the first inorganic encapsulation layer, the organic encapsulation layer and the second inorganic encapsulation layer are stacked,
the at least one inorganic film comprises a first inorganic film, and
the second inorganic encapsulation layer is connected to the first inorganic film.

8. The display apparatus of claim 7, wherein the sensing electrode is disposed between the first display element and the second display element.

9. The display apparatus of claim 7, wherein the input sensing unit further comprises an organic insulating layer disposed on the sensing electrode.

10. The display apparatus of claim 2, wherein a thickness of the organic encapsulation layer is about 3 μm to about 15 μm,
a refractive index of the first inorganic encapsulation layer is about 1.55 to about 1.85, and
at least one of a thickness of the first inorganic encapsulation layer, the first thickness of the second inorganic encapsulation layer, or the second thickness of the second inorganic encapsulation layer is less than the thickness of the organic encapsulation layer.

11. The display apparatus of claim 10, wherein, the first thickness of the second inorganic encapsulation layer is about 0.7 μm, and the second thickness of the second inorganic encapsulation layer is about 0.8 μm.

12. The display apparatus of claim 10, wherein the first inorganic encapsulation layer comprises at least one of silicon oxide, silicon nitride, or silicon oxynitride.

13. The display apparatus of claim 1, wherein the refractive index of the at least one organic encapsulation layer is about 1.45 to about 1.55.

14. The display apparatus of claim 1, further comprising a planarization film disposed on the thin-film encapsulation layer.

15. A display apparatus comprising:
a substrate comprising a display area and a non-display area;
a display layer comprising a first display element and a second display element arranged in the display area; and
a thin-film encapsulation layer arranged to cover the display layer and comprising a first inorganic encapsulation layer, an organic encapsulation layer, and a second inorganic encapsulation layer,
wherein a refractive index of the organic encapsulation layer is less than refractive indices of the first inorganic encapsulation layer and the second inorganic encapsulation layer,
a thickness of the organic encapsulation layer is about 3 μm to about 15 μm,
the refractive index of the first inorganic encapsulation layer is about 1.55 to about 1.85, and
a first thickness of a first portion of the second inorganic encapsulation layer corresponding to the first display element is different from a second thickness of a second portion of the second inorganic encapsulation layer corresponding to the second display element.

16. The display apparatus of claim 15, wherein the display layer further comprises a third display element, and
a third thickness of a third portion of the second inorganic encapsulation layer corresponding to the third display element is different from the first thickness and the second thickness.

17. The display apparatus of claim 15, further comprising an input sensing unit comprising an inorganic film and a sensing electrode disposed on the thin-film encapsulation layer,
wherein a first total thickness of the first portion of the second inorganic encapsulation layer and the inorganic film, each of which correspond to the first display element, is different from a second total thickness of the second portion of the second inorganic encapsulation layer and the inorganic film, each of which correspond to the second display element.

18. The display apparatus of claim 15, further comprising a planarization film disposed on the thin-film encapsulation layer.

19. The display apparatus of claim 15, wherein at least one of a thickness of the first inorganic encapsulation layer, the first thickness of the first portion of the second inorganic encapsulation layer, or the second thickness of the second portion of the second inorganic encapsulation layer is less than the thickness of the organic encapsulation layer.

20. A display apparatus comprising:
a substrate comprising a display area;
a display layer comprising display elements arranged on the display area; and
a thin-film encapsulation layer disposed on the display layer and comprising a first inorganic encapsulation layer, an organic encapsulation layer, and a second inorganic encapsulation layer,
wherein a refractive index of the organic encapsulation layer is less than refractive indices of the first inorganic encapsulation layer and the second inorganic encapsulation layer,
a thickness of the organic encapsulation layer is about 3 μm to about 15 μm,
the refractive index of the first inorganic encapsulation layer is about 1.55 to about 1.85, and
a thickness of the first inorganic encapsulation layer and a thickness of the second inorganic encapsulation layer are less than the thickness of the organic encapsulation layer.
